(19) United States
(12) Patent Application Publication
(10) Pub. No.: US 2009/0245537 A1
(43) Pub. Date: Oct. 1, 2009

(54) AUTOMATIC IPOD VOLUME ADJUSTMENT

(76) Inventor: MICHELLE MORIN, Ottawa (CA)

Correspondence Address: J. GORDON THOMSON, P.O. BOX 8865, VICTORIA, BC, V8V 3Z1, CA

(21) Appl. No.: 12/057,305

(22) Filed: Mar. 27, 2008

(51) Int. Cl. H03G 3/20

(52) U.S. Cl. 381/107

(57) ABSTRACT

A program that would take the average db level of a music device after a certain amount of time and record at the same time the amount of time the user has been listening to the music device. The program would then automatically adjusts the volume level so that the LEQ would be at a safe level in relation to the amount of noise (music) the user has been exposed to.

### FIELD OF THE INVENTION

This invention relates to a system for alerting users to when they are at risk of damaging their hearing while using an audio/music device.

1. Background

Portable audio and music devices are becoming increasingly popular, especially with a younger demographic. Young adults especially are prone to listening to their music devices for hours on end, without considering the volume at which they are listening. Especially now, with MP3 players that are louder and have better sound quality, people are damaging their hearing without even noticing it.

NIHL (Noise Induced Hearing Loss, which is caused by exposure to an extremely loud noise or frequent exposure to a dangerous noise level over a certain period of time) is increasingly becoming a significant problem, with symptoms not expected to appear before middle-age manifesting themselves in teen-agers. In fact, out of the 40 million people in America with hearing loss, 10 million of them suffer from NIHL.

There is, therefore, a need for a system that will prevent damage caused by unknowing playing music at dangerous volumes. Accordingly, the problem addressed by this invention is to make a program that can be put on an MP3 player and would automatically reduce the volume according to the Leq (equivalent sound pressure related to the average decibel level). This would increase the user's chance of not damaging their hearing by providing a damage prevention mechanism.

The inventors got the idea for this invention while wondering how long they could safely listen to their iPod. They were amazed that to find that you can only listen to your iPod at full volume for only 2 minutes without damaging your hearing. The problem is solved by creating a program that will prevent damage to the ear that is simple to use, easy and reliable to activate, and cost effective enough to allow mass wide scale commercial adoption including by youth.

A specific system implemented to solve this problem is called “iHear”, though other variations of the concept are possible.

2. Prior Art

The following discussion identifies the prior art of which the Inventors are aware. A description of each reference is provided followed by a brief explanation as to how the present invention distinguishes the reference. All the references deal with audio control. None extend this system by tracking the total sound exposure by volume and time played and providing notice or sound limiting, as in the present invention, such that it can be easily integrated into the audio player devices. The system of the present invention can also made ubiquitous cost effective by using existing devices and systems.

U.S. Pat. No. 7,319,764—Method and apparatus for controlling volume. Some embodiments of the invention provide a method for controlling the volume of an audio track. This method represents the volume of an audio track with a graph. This graph is defined along two axes, with one axis representing time and the other representing the volume level. A user can adjust the graph at different instances in time in order to change the volume level in the audio track at these instances. Different embodiments use different types of graphs to represent volume. For instance, some embodiments use a deformable line bar.

Differences: The main difference in the above patent is that it relates to the user being able to change the volume at points within a song. iHear does not allow variation of control within a song but tracks the total volume exposure and can automatically adjust the volume to protect your hearing, or provide a user alert notification to turn, down the volume.

U.S. Pat. No. 7,319,761—Method and apparatus for locating and correcting sound overload. The invention describes a graphical method for detecting and adjusting audio overload conditions. The graphical user interface provides a user complete playback control of several audio tracks, detection of overload conditions such as audio clipping, and graphical methods to correct the overload conditions. The graphical interface provides drag handles which the user can use to adjust the various characteristics of an audio file. The characteristics, such as amplitude and temp, may be adjusted as a function of time.

Differences: The main difference in the above patent is that it relates to the detection of volume overload at an instantaneous point in time and to modify the music characteristics at these points. It does not track total exposure to protect hearing. iHear does not allow variation of control within a song but tracks the total volume exposure and can automatically adjust the volume to protect your hearing, or provide a user alert notification to turn down the volume.

U.S. Pat. No. 7,088,834—Audio apparatus, audio volume control method in audio apparatus, and computer apparatus. An audio apparatus that enables audio output and volume to be controlled according to the usage situation is provided for. In an audio apparatus of the present invention, certain hypothetical connection situations are compared with actual connection situations, and when the actual connection situation matches a described hypothetical connection situation, the audio volume corresponding to that hypothetical connection situation is extracted from storage, and is used as the audio volume to be output from the audio apparatus.

Differences: The difference is that the above patent can control the volume level as a function of the usage environment, but does not track the human ear total volume exposure nor attempt to protect it.

U.S. Pat. No. 6,868,162—Method and apparatus for automatic volume control in an audio system. An audio system is provided with improved adaptive filter to automatically adjust signal gain depending on the ambient noise level. The original music signal passes through a normalized adaptive filter, and is subtracted from the ambient room signal detected by a microphone, resulting in an error signal that is an estimate of the ambient noise. The error signal is used to update a set of adaptation coefficients so that the normalized adaptive filter more accurately simulates the room transfer function, resulting in a better estimate of the ambient noise. The audio system is calibrated automatically upon initial use to determine adaptation coefficients and noise threshold level to prevent runaway gain. System parameters are adjusted using a controller with a user-friendly interface.

Differences: In this case, the volume is adjusted automatically to the surrounding noise level so that you can hear it, whereas iHear tracks the total volume exposure and can adjust the volume automatically according to the average volume you've listened to it at and the amount of time you've done so, in order to protecting your hearing.

U.S. Pat. No. 6,298,247—Method and apparatus for automatic volume control. An apparatus is disclosed for automatically controlling the volume level of an audio signal transmitted to or received by a mobile station and/or terminal within a telecommunications network, the apparatus including a noise measuring device, a volume controller communicably coupled to the noise measuring device, and a memory module communicably coupled to the noise measuring device. In a wireless telecommunications network, the memory module may comprise a subscriber identity module (SIM) and contain preferred volume levels for given levels of noise for that particular subscriber. A method is also disclosed for automatically controlling the volume level of an audio signal transmitted to or received by a phone terminal and/or mobile station within a telecommunications network, comprising the steps of obtaining measurements of a background noise signal, obtaining a preferred volume level corresponding to the measurement of a background noise signal, and automatically adjusting the volume level of the audio signal to the preferred volume level.

Differences: the above patent relates to volume control as a function of transmission networks and ambient noise, but does not track the total volume exposure to the human ear nor takes steps the use this as a factor in adjusting the volume level.

### SUMMARY OF THE INVENTION

There exists dynamic volume controls and maximum volume limiters for audio players, but no previous system that tracks total sound exposure can implement a limit on the total sound exposure in a limited time. The proposed system is only activated by the user when desired, and can automatically limit the sound level or can provide a warning notice to the user of the safe listening time remaining at that level.

The invention uses the principal of Leq—which is the Long-term Equivalent Level or average decibel level being played and the amount of time the user has devoted to listening to the audio device to make sure hearing wasn't being damaged. It works by using a software program to track what the decibel level output by the player is every five seconds, and take the average of them, approximating the Leq. This average db level is then used to determine how long the user can listen to the device at that volume, and to provide a warning when the safe limit is reached or automatically turn clown the volume when needed.

The solution also solves the problem of the user increasing or decreasing the volume of the audio player. The timer used for the safe listening time can be adjusted to the actual sound exposure and would never go back to zero, until the player is turned off for a safe period of time. The program can track whether it could continue playing at this new volume, and reduce it later if needed, or turn it down right away. The program would decrease the volume if needed and display the reduced volume on the visual display.

The invention allows an individual to be protected from auditory damage caused by excessive, cumulative volume levels. The novelty of this invention is it is embedded control software in the player itself, and which controls, in a preferred embodiment, the volume output from the audio player to levels which are dynamically adjusted to reflect the actual audio played. Alternative embodiments include user notification and a message indicating the total amount of safe time remaining at that level, and which level is a new safe level, or how much time is needed with no audio output in order to resume at the current level.

The maximum safe level of sound exposure would be programmed to a normal human ear safe level but can allow user-controlled reduction of the safe level, for instance for users with hearing sensitivities or for an additional margin of safety.

Therefore in accordance with a first aspect of the present invention there is provided a system for measuring and providing an alerting message to the user about excessive cumulative volume.

In accordance with a second aspect of the invention there is provided a method of automatically controlling the audio output level to a level that protects the user from hearing damage caused by excessive cumulative levels.

### BRIEF DESCRIPTION OF THE DRAWINGS

The invention will now be described in greater detail with reference to the attached drawings wherein:

FIG. 1 illustrates the overall concept of the invention including functional blocks, information flows and participating entities; and

FIG. 2 illustrates the overall operation of the invention.

### DETAILED DESCRIPTION OF THE INVENTION

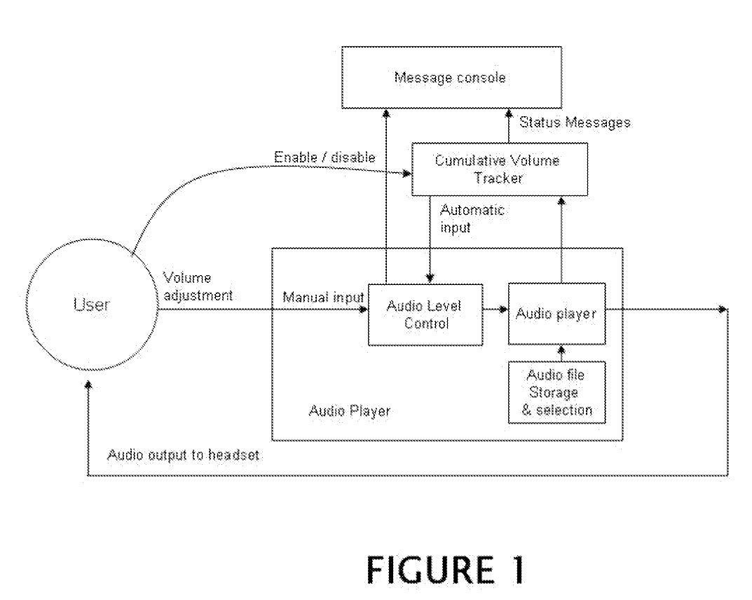

The generic embodiment of the invention is captured in FIG. 1. It captures the overall concept including functional blocks, information flows, and the participating entities. The key participating entities within the operational framework are: User, Audio Player device, and Cumulative Volume Tracker. Each functional block and the participating key entities are described in further details below:
a) User: The operator of the personal audio/music player. This user will have access to the device controls, graphical user interface, and audio output (A typical user is an iPod user listening on personal headphones.)
b) Audio Player Device: any personal audio player device including iPods, MP3 players, personal entertainment systems in vehicles, portable disc and tape players etc. . . . .
c) Cumulative Volume tracker: a system for measuring or computing actual audio output levels.

The following describes the key functional blocks:
c) Audio Volume Level Control: for the user to adjust the volume output level of the device
d) Audio File Storage & Selection: the contents of the audio to be played
e) Audio Player: the audio player itself
f) Cumulative Volume Tracker: a mechanism that monitors the actual cumulative output volume of the player, averages this over time, detects when the maximum level is reached, and provides an alert to the user via the visual display screen, and optionally automatically reduces the volume of the audio player. It can also provide to the display screen the remaining “safe” time to listen at a given volume level.
g) Visual Display Control: display of the volume output level of the device, as set by the user and/or as adjusted by the volume limiter. It also is used to display warning/alert messages if the automatic volume control is disabled.

Example Specific Implementation:

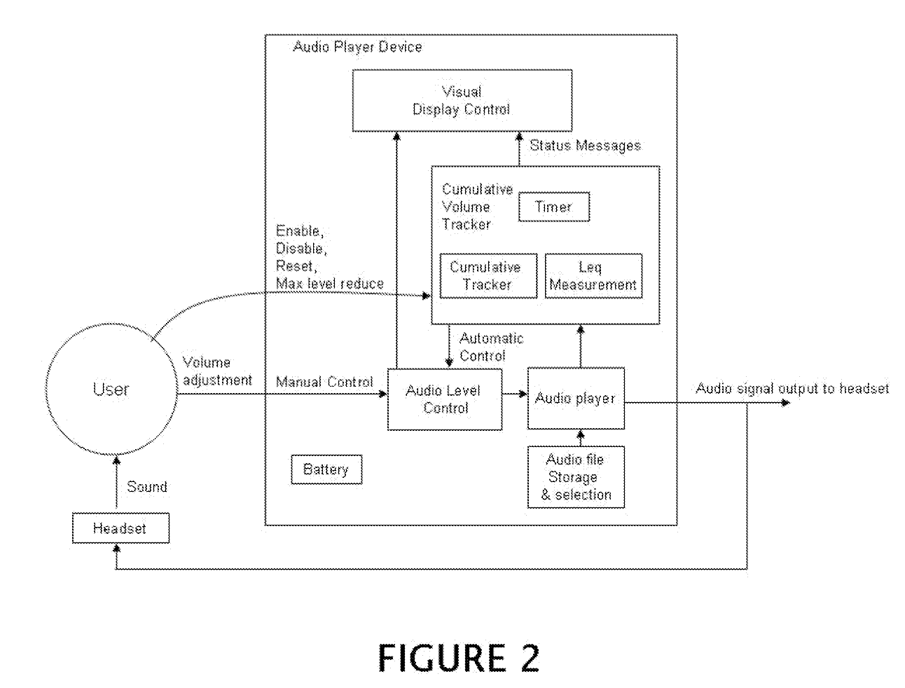

One embodiment of the invention is captured in FIG. 2. It captures the overall operation framework including functional blocks, information flows, and the participating entities. Each functional block and the participating entities are described in further details below:

### Key Entities

a) User: The operator of the personal audio/music player. This user will have access to the device controls, graphical user interface, and audio output (A typical user is an iPod user listening on personal headphones.)
b) Audio Player Device: any personal audio player device including iPods, MP3 players, personal entertainment systems in vehicles, portable disc and tape players etc.

### Key Functional Blocks:

c) Audio Volume Level Control: for the user to adjust the volume output level of the device
d) Audio File Storage & Selection: the contents of the audio to be played
e) Audio Player: the audio player itself
f) Cumulative Volume Tracker: a mechanism that monitors the actual cumulative output volume of the player, averages this over time, detects when the maximum level is reached, and provides an alert to the user via the visual display screen, and optionally automatically reduces the volume of the audio player. It can also provide to the display screen the remaining “safe” time to listen at a given volume level.

The device includes the following aspects:
1. Leq Measurement: a technique (other similar techniques may be used) that measures the average audio output levels. An external Leq measurement environment may be used to determine Leq vs. volume settings for particular music or players, or may be included in the unit itself.

2. Cumulative tracker: totals up the time and volume at which the player is operated, and determines when the safe amount of total sound has been reached. It then takes the configured action—automatically limit the volume to a safe level, and/or displays messages to the screen.

3. Timer: used to track running times of the player at the various levels, as well as rest time between sessions.
g) Visual Display Control: display of the volume output level of the device, as set by the user and/or as adjusted by the volume limiter. It also is used to display warning/alert messages if the automatic volume control is disabled.
h) Battery: provides power for portable audio players
i) Headset: converts the audio signal to sound input to the human ear.

Other functional aspects of the system:
Device Configuration: The iHear device is configured with information which determines the “safe” levels as a default or to a reduced level, to automatically limit volume or display a warning message, and to enable and disable the operation of iHear.
Status Messages: Messages that are sent to the visual display screen of the player to provide user notification such as “safe time & volume exceed, volume has been reduced” or “Please reduce volume now to avoid hearing damage”.

This following describes the method of using the invention in the above embodiment. The embodiment of the invention is portable music player with integrated volume tracking and status message displays. The system has been called “iHear” by the inventors since it protects the users ability to have undamaged hearing even after listening to the player for many years.

The invention proposed is a program that could be put on a music device to regulate the amount of music your ear hears, in order to reduce one's chance at getting Noise Induced Hearing Loss due to music devices.

To do this, the program would track the played volume level as LEQ (equivalent continuous sound level) by computing the decibel level after a certain amount of time.

The program would also track the amount of time the music device has been playing, and use this number to know at what level the user can listen to the music without their hearing being damaged.

If the leq is higher than the safe decibel level for the amount of time the user had been listening to the device, the program would automatically reduce the volume so that when it measured the decibel level again, the LEQ would be at a low enough level for the time.

The safe LEQ would be based on the amount of time one can listen to a certain level before damaging their hearing, as represented in the table below:

| | | | |
|---|---|---|---|
| 85 | dBs: | 480 | minutes (8 hours) |
| 88 | dBs: | 240 | minutes (4 hours) |
| 91 | dBs: | 120 | minutes (2 hours) |
| 94 | dBs: | 60 | minutes (1 hour) |
| 97 | dBs: | 30 | minutes |
| 100 | dBs: | 15 | minutes |
| 103 | dBs. | 7.5 | minutes (7 minutes 30 seconds) |
| 106 | dBs: | 3.75 | minutes (3 minutes 45 seconds) |
| 109 | dBs: | 1.875 | minutes (1 minute 52 seconds) |
| 112 | dBs: | 0.9375 | minutes (56 seconds) |
| 115 | dBs: | 0.46875 | minutes (28 seconds) |

If the LEQ were at any of these levels, and the time the user had been listening to the device grater than the sate time listed, the volume would be automatically reduced. Since the timer in the program does not turn off, there would be no problem if the user decided to turn the volume up on the device. The LEQ would simply increase. However, if the user turned the volume up to a dangerous level for the amount of time he had been listening to the device (eg the LEQ is now 100 decibels, and he has been listening to the device for 28 minutes), then the volume would be turned down right away to a safer level.

If the LEQ is still at a safe volume until the user turns it up, then it will just keep playing until the safe time at that level has elapsed, and then turn it down.

The following provides a C++ Program to run on the “Rockbox” open-source development system to implement the iHear system of the present invention.

```
#include “dsp.h”
#include “action.h”
#include “cuesheet.h”
+static int warned;
+static int time_past;
+static int last_check_time;
#ifdef HAVE_LCD_CHARCELLS
static bool draw_player_progress(struct gui_wps *gwps);
static void draw_player_fullbar(struct gui_wps *gwps,
case ‘v’: /* volume */
        *flags |= WPS_REFRESH_DYNAMIC;
− snprintf(buf, buf_size, “%d”, global_settings.volume);
+ int num = global_settings.volume + 108;
+ if (num < 81)
+ {
+ snprintf(buf, buf_size, “Max: Unlimited, %d”,
global_settings.volume);
+ }
+ if (num > 80 && num < 86)
+ {
+ snprintf(buf, buf_size, “Max: 8 hours, %d”,
global_settings.volume);
+ }
+ if (num > 85 && num < 91)
+ {
+ snprintf(buf, buf_size, “Max: 4 hours, %d”,
global_settings.volume);
+ }
+ if (num > 90 && num < 96)
+ {
+ snprintf(buf, buf_size, “Max: 2 hours, %d”,
global_settings.volume);
+ }
+ if (num > 95 && num < 101)
+ {
+ snprintf(buf, buf_size, “Max: 1 hour, %d”,
global_settings.volume);
+ }
+ if (num > 100 && num < 106)
+ {
+ snprintf(buf, buf_size, “Max: 30 minutes, %d”,
global_settings.volume);
+ }
+ if (num > 105)
+ {
+ snprintf(buf, buf_size, “Max: 15 minutes, %d”,
global_settings.volume);
+ }
*intval = limit * (global_settings.volume
sound_min(SOUND_VOLUME))
            / (sound_max(SOUND_VOLUME)
    if (gwps->state->id3)
      memcpy(gwps->state->current_track_path,
      gwps->state->id3->path,
        sizeof(gwps->state->current_track_path));
− }
+ }
  if (gwps->state->id3)
{
  if (cuesheet_is_enabled( ) && gwps->state->id3->cuesheet_type
  else
      gui_wps_refresh(gwps, 0, WPS_REFRESH_NON_STATIC);
  }
+if (warned != 1){
+if (last_check_time == 0)
+ {
+ last_check_time = current_tick;
+ }
+ if (global_settings.volume > sound_min(SOUND_VOLUME))
+ {
+ time_past = time_past + (current_tick − last_check_time);
+ last_check_time = current_tick;
+int sec = time_past / HZ;
+int min = sec / 60;
+ int num = global_settings.volume + 108;
+ if ( (num > 80 && num < 86 && min > 480) ||
+ (num > 85 && num < 91 && min > 240) ||
+ (num > 90 && num < 96 && min > 120) ||
+ (num > 95 && num < 101 && min > 60) ||
+ (num > 100 && num < 106 && min > 30) ||
+ (num > 105 && min > 15) )
+ {
+ gui_syncsplash(HZ*2, true, “Warning”);
+ warned = 1;
+ }
+ }
+}
    gui_wps_statusbar_draw(gwps, false);
    return retcode;
```

We claim:

1. A system for protecting the hearing of users of personal audio players consisting of:
an audio player device adapted to track the playing volume, generate alert messages, and automatically control the volume of the player.

2. The system as defined in claim 1 wherein the volume measuring device is separate and removed from the audio player but is still used to control the volume of the player to a safe level.

3. The system as defined in claim 2 wherein the results of the cumulative volume measurement are used to control the volume of the player.

4. The system as defined in claim 2 wherein results of the cumulative volume measurement are used to provide status updates and alerts to the user via the graphical display screen.

5. The system as defined in claim 2 further having timing functionality whereby the alert message includes the time of remaining operation at the current volume level before risk of damage to hearing.

6. The system as defined in claim 1 wherein the audio player device is one of an iPod, MP3 player, cell phone, Personal Digital Assistant (PDA), disc players, tape players, or audio system embedded in a vehicle including automobiles and airplanes.
